(19) United States
(12) Patent Application Publication
(10) Pub. No.: US 2025/0006533 A1
(43) Pub. Date: Jan. 2, 2025

(54) SUBSTRATE CONVEYANCE METHOD AND SUBSTRATE CONVEYANCE DEVICE

(71) Applicant: TOKYO ELECTRON LIMITED, Tokyo (JP)

(72) Inventors: Wataru MATSUMOTO, Yamanashi (JP); Takehiro SHINDO, Yamanashi (JP); Tatsuru OKAMURA, Miyagi (JP); Nanako SHINODA, Yamanashi (JP); Junpei SASAKI, Yamanashi (JP)

(21) Appl. No.: 18/697,729

(22) PCT Filed: Oct. 13, 2021
(86) PCT No.: PCT/JP2021/037832

§ 371 Date: Apr. 1, 2024

(51) Int. Cl. H01L 21/677; H01L 21/67; H01L 21/68

(52) U.S. Cl. CPC H01L 21/67745; H01L 21/67259; H01L 21/67742; H01L 21/68

(57) ABSTRACT

This substrate conveyance method is disclosed for a conveyance device. A conveyance chamber includes a conveyance mechanism having forks, on upper and lower sides, and support a substrate. A buffer chamber is connected to the conveyance chamber, and includes: a mounting unit that mounts a substrate; and, pins that support the substrate. In the method, the conveyance mechanism, with a second substrate supported by the lower fork, is inserted into the buffer chamber in which a first substrate is mounted on the mounting unit, and the first substrate is lifted by the upper fork. In the method, the pins are raised while the first substrate is lifted by the upper fork, and the second substrate supported by the lower fork is lifted by the pins. In the method, the conveyance mechanism is removed from the buffer chamber while the second substrate is lifted by the pins.

### TECHNICAL FIELD

The present disclosure relates to a substrate transfer method and a substrate transfer device.

### BACKGROUND

Patent Document 1 discloses a technique in which a first transfer arm and a second transfer arm that can operate individually in a transfer chamber, a processed substrate is received by the first transfer arm from a processing chamber, and an unprocessed substrate is transferred by the second transfer arm to the processing chamber.

### PRIOR ART DOCUMENTS

### Patent Documents

Patent Document 1: JP Patent Publication No. 2012-174716

### SUMMARY

### Problems to be Resolved by the Invention

The present disclosure provides a substrate transfer method and a substrate transfer device through which a time required to exchange substrates can be reduced.

### Means for Solving the Problems

A substrate transfer method according to one aspect of the present disclosure is a substrate transfer method of a transfer device having a transfer chamber and a buffer room. The transfer chamber is provided with a transfer mechanism having two forks, on an upper side and a low side, which can support a substrate. The buffer chamber is provided with a mounting part capable of mounting a substrate by contacting a portion of the substrate, and a plurality of pins capable of supporting the substrate by being raised and lowered below the mounting part, and is connected to the transfer chamber. In the substrate transfer method, the transfer mechanism having a second substrate supported by the lower fork enters the buffer chamber in which a first substrate is mounted on the mounting part, and the first substrate mounted on the mounting part is lifted by the upper fork. In the substrate transfer method, the plurality of pins is raised in a state in which the first substrate is lifted by the upper fork, and the second substrate supported by the lower fork is lifted by the plurality of pins. In the substrate transfer method, the transfer mechanism is retracted from the buffer chamber in a state in which the second substrate is lifted by the plurality of pins.

### Effect of the Invention

According to the present disclosure, a time required to exchange substrates can be reduced.

### BRIEF DESCRIPTION OF THE DRAWINGS

FIG. 1 is a plan view schematically showing an example of a substrate processing system according to an embodiment.

FIG. 2 is a perspective view showing an example of the configuration of a robot arm according to an embodiment.

FIG. 3 is a plan view showing an example of the configuration of a third arm according to an embodiment.

FIG. 4 is a cross-sectional view schematically showing an example of the configuration of a load lock module (LLM) according to an embodiment.

FIG. 5 is a plan view schematically showing an example of the configuration of the LLM according to the embodiment.

FIG. 6 is a cross-sectional view schematically showing an example of the configuration of a buffer chamber according to an embodiment.

FIG. 7 is a plan view schematically showing an example of the configuration of the buffer chamber according to the embodiment.

FIG. 8A is a diagram illustrating a flow of transfer in an LLM in the substrate processing system according to the embodiment.

FIG. 8B is a diagram illustrating the flow of transfer in the LLM in the substrate processing system according to the embodiment.

FIG. 8C is a diagram illustrating the flow of transfer in the LLM in the substrate processing system according to the embodiment.

FIG. 8D is a diagram illustrating the flow of transfer in the LLM in the substrate processing system according to the embodiment.

FIG. 8E is a diagram illustrating the flow of transfer in the LLM in the substrate processing system according to the embodiment.

FIG. 8F is a diagram illustrating the flow of transfer in the LLM in the substrate processing system according to the embodiment.

FIG. 8G is a diagram illustrating the flow of transfer in the LLM in the substrate processing system according to the embodiment.

FIG. 9A is a diagram illustrating the flow of transfer in the LLM in the substrate processing system according to the embodiment.

FIG. 9B is a diagram illustrating the flow of transfer in the LLM in the substrate processing system according to the embodiment.

FIG. 9C is a diagram illustrating the flow of transfer in the LLM in the substrate processing system according to the embodiment.

FIG. 9D is a diagram illustrating the flow of transfer in the LLM in the substrate processing system according to the embodiment.

FIG. 9E is a diagram illustrating the flow of transfer in the LLM in the substrate processing system according to the embodiment.

FIG. 9F is a diagram illustrating the flow of transfer in the LLM in the substrate processing system according to the embodiment.

FIG. 9G is a diagram illustrating the flow of transfer in the LLM in the substrate processing system according to the embodiment.

FIG. 9H is a diagram illustrating the flow of transfer in the LLM in the substrate processing system according to the embodiment.

FIG. 10A is a diagram illustrating a flow of transfer in the buffer chamber in the substrate processing system according to the embodiment.

FIG. 10B is a diagram illustrating the flow of transfer in the buffer chamber in the substrate processing system according to the embodiment.

FIG. 10C is a diagram illustrating the flow of transfer in the buffer chamber in the substrate processing system according to the embodiment.

FIG. 10D is a diagram illustrating the flow of transfer in the buffer chamber in the substrate processing system according to the embodiment.

FIG. 10E is a diagram illustrating the flow of transfer in the buffer chamber in the substrate processing system according to the embodiment.

FIG. 11A is a diagram illustrating the flow of transfer in the buffer chamber in the substrate processing system according to the embodiment.

FIG. 11B is a diagram illustrating the flow of transfer in the buffer chamber in the substrate processing system according to the embodiment.

FIG. 11C is a diagram illustrating the flow of transfer in the buffer chamber in the substrate processing system according to the embodiment.

FIG. 11D is a diagram illustrating the flow of transfer in the buffer chamber in the substrate processing system according to the embodiment.

FIG. 11E is a diagram illustrating the flow of transfer in the buffer chamber in the substrate processing system according to the embodiment.

FIG. 12 is a flowchart showing an example of a processing flow of a substrate transfer method according to an embodiment.

FIG. 13 is a flowchart showing an example of a processing flow of a substrate transfer method according to an embodiment.

### DETAILED DESCRIPTION

Hereinafter, embodiments of the disclosed substrate transfer method and substrate transfer device will be described in detail on the basis of the drawings. In addition, the disclosed technology is not limited to the following embodiments.

A substrate processing system has a vacuum transfer chamber for transferring substrates to a process module that processes the substrates. The substrate processing system connects a load lock, the inside of which can be switched between a depressurized state and an atmospheric state, to the vacuum transfer chamber, and exchanges an unprocessed substrate and a processed substrate through the load lock. For example, the vacuum transfer chamber is provided with a transfer mechanism such as a transfer arm. The transfer mechanism unloads a substrate from the load lock and transfers the unloaded substrate to a selected process module. Additionally, the transfer mechanism transfers a processed substrate to the next process module or load lock.

Additionally, the substrate processing system may have a configuration in which a plurality of vacuum transfer chambers is connected by a buffer chamber. In this case, the transfer mechanism in each vacuum transfer chamber exchanges substrates through the buffer chamber.

In this manner, when exchanging an unprocessed substrate and a processed substrate in the load lock or the buffer chamber, the time taken to exchange the substrates increases since one substrate is unloaded and then the other substrate is disposed.

Therefore, it is expected to reduce the time required to exchange substrates.

### Embodiment

### [Configuration of Substrate Processing System 1]

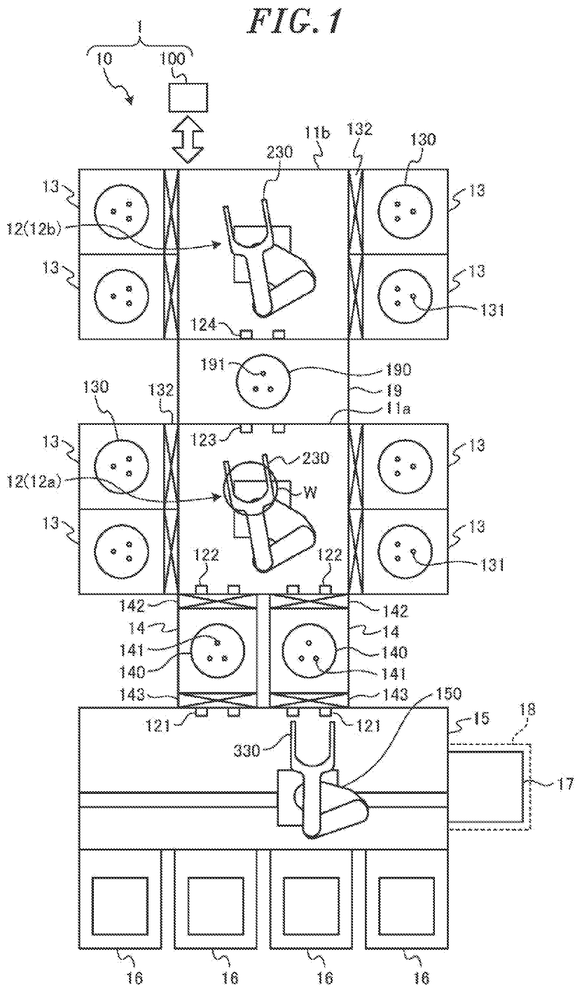

An embodiment will be described. First, a substrate processing system 1 according to the embodiment will be described. FIG. 1 is a plan view schematically showing an example of the substrate processing system 1 according to the embodiment. The substrate processing system 1 shown in FIG. 1 is a substrate processing system capable of performing various processes, such as plasma processing, on a substrate W such as a semiconductor wafer, for example.

The substrate processing system 1 includes a processing system body 10 and a control device 100 that controls the processing system body 10. For example, as shown in FIG. 1, the processing system body 10 includes vacuum transfer chambers 11a and 11b, a plurality of process modules 13, a plurality of load lock modules 14, and an equipment front end module (EFEM) 15. In addition, in the following description, the vacuum transfer chambers 11a and 11b are referred to as vacuum transfer modules (VTMs) 11a and 11b, the process module 13 is represented as a PM 13, and the load lock module 14 is represented as an LLM 14.

The VTMs 11a and 11b each have a substantially square shape when viewed from the top. A plurality of PMs 13 is connected to two opposing sides of each of the VTMs 11a and 11b. Additionally, the LLMs 14 are connected to one side of the two opposing sides of the VTM 11a, and a buffer chamber 19 for connection to the VTM 11b is connected to the other side. The VTM 11b is connected to the VTM 11a via the buffer chamber 19. The VTMs 11a and 11b have vacuum chambers in a predetermined depressurized state. Robot arms 12 (12a and 12b) are disposed inside the VTMs 11a and 11b, respectively. In the present embodiment, the VTMs 11a and 11b, the LLMs 14, the EFEM 15, and the buffer chamber 19 correspond to the substrate transfer device of the present disclosure.

The robot arms 12a and 12b are configured to be capable of turning, stretching, and moving up and down. The robot arms 12a and 12b can transfer the substrate W between the PMs 13, the LLMs 14, and the buffer chamber 19 by mounting the substrate W on a fork 230 provided at the tip. The robot arms 12a, 12b, and a robot arm 150 which will be described later are examples of a transfer mechanism of the present disclosure.

The substrate processing system 1 is provided with a plurality of sensors for detecting the position of the substrate W. For example, in the substrate processing system 1, two sensors 121 are arranged for each LLM 14 above a position where the substrate W passes near the connection portion between the LLM 14 and the EFEM 15. The two sensors 121 arranged for each LLM 14 acquires sensing information on the substrate W when the robot arm 150 in the EFEM 15 loads/unloads the substrate W into/from the LLM 14. In addition, in the substrate processing system 1, two sensors 122 are disposed for each LLM 14 above a position where the substrate W passes near the connection portion between the VTM 11a and the LLM 14. The two sensors 122 arranged for each LLM 14 acquire sensing information on the substrate W when the robot arm 12a loads/unloads the substrate W into/from the LLM 14. Additionally, in the substrate processing system 1, two sensors 123 are arranged above a position where the substrate W passes near the connection portion between the VTM 11a and the buffer chamber 19. The two sensors 123 acquire sensing information about the substrate W when the robot arm 12a loads/unloads the substrate W into/from the buffer chamber 19. Additionally, in the substrate processing system 1, two sensors 124 are disposed at the upper portion of the position where the substrate W passes near the connection portion between the VTM 11b and the buffer chamber 19. The two sensors 124 acquire sensing information on the substrate W when the robot arm 12b loads/unloads the substrate W into/from the buffer chamber 19. Additionally, the sensors 121 to 124 are provided as pairs, but three or more may be provided each. The sensors 121 to 124 may be disposed at any position and may have any configuration as long as they can detect the position of the substrate W. For example, the sensors 121 to 124 may be configured to detect the position of the substrate W from the sides.

The PM 13 has a processing chamber and a cylindrical stage 130 (mount) disposed inside. The stage 130 has three lift pins 131 in the shape of a thin rod that can protrude from the upper surface. The lift pins 131 are disposed on the same circumference when viewed from the plane of the stage 130. Each lift pin 131 supports and lifts the substrate W mounted on the stage 130 by protruding from the upper surface of the stage 130. Additionally, each lift pin 131 mounts the supporting substrate W on the stage 130 by being retracted into the stage 130. After the substrate W is mounted on the stage 130, the PM 13 depressurizes the inside, introduces a processing gas, additionally applies high-frequency power to the inside to generate plasma, and performs plasma processing on the substrate W. The VTM 11a and 11b and the PM 13 are partitioned by a gate valve 132 that can be opened and closed.

The LLM (14) is disposed between the VTM 11a and the EFEM 15. The LLM 14 has an internal pressure variable chamber inside of which can be switched to a predetermined depressurized state or an atmospheric pressure state, and has a cylindrical stage 140 disposed therein.

When transferring the substrate W from the EFEM 15 to the VTM 11a, the LLM 14 maintains the inside at atmospheric pressure and, after receiving the substrate W from the EFEM 15, depressurizes the inside and loads the substrate W into the VTM 11a. Additionally, when transferring the substrate W from the VTM 11a to the EFEM 15, the LLM 14 maintains the inside in a depressurized state, and after receiving the substrate W from the VTM 11a, increase the pressure of the inside to atmospheric pressure, and loads the substrate W into the EFEM 15. The stage 140 has three lift pins 141 in the shape of a thin rod that can protrude from the upper surface. The lift pins 141 are disposed on the same circumference when viewed from the plane. Each lift pin 141 supports and lifts the substrate W by protruding from the upper surface of the stage 140. Additionally, each lift pin 141 mounts the supporting substrate W on the stage 140 by being retracted into the stage 140. The LLM 14 and the VTM 11a are partitioned by agate valve 142 that can be opened and closed. Additionally, the LLM 14 and the EFEM 15 are partitioned by a gate valve 143 that can be opened and closed.

The EFEM 15 is disposed opposite to the VTM 11a. The EFEM 15 has a rectangular parallelepiped shape and includes a fan filter unit (FFU), and is an atmospheric transfer chamber held in an atmospheric pressure atmosphere. Two LLMs 14 are connected to one side in the longitudinal direction of the EFEM 15. Four load ports (LPs) 16 are connected to the other side in the longitudinal direction of the EFEM 15. The LPs 16 are equipped with a front-opening unified pod (FOUP) (not shown), which is a container for accommodating a plurality of substrates W. An aligner 17 and a mapping temporary port (MTP) 18 are connected to one side in the width direction of the EFEM 15. Additionally, the robot arm 150 is disposed within the EFEM 15.

The robot arm 150 is configured to be movable along a guide rail. In addition, the robot arm 150 has the same configuration as the robot arm 12 and is configured to be capable of turning, stretching, and moving up and down. The robot arm 150 can transfer a substrate W between the FOUP of the LP 16, the aligner 17, the MTP 18, and the LLM 14 by mounting the substrate W on the fork 230 disposed at the tip. Additionally, the robot arm 150 may be capable of transferring the substrate W between the FOUP, the aligner 17, the MTP 18, and the LLM 14, and is not limited to the configuration shown in FIG. 1.

The aligner 17 performs alignment of the substrate W. The aligner 17 has a rotary stage (not shown) that is rotated by a drive motor (not shown). The rotary stage has a diameter less than that of the substrate W, for example, and is configured to be rotatable with the substrate W mounted on the upper surface thereof. An optical sensor for detecting the outer periphery of the substrate W is provided near the rotary stage. In the aligner 17, the center position of the substrate W and the direction of a notch with respect to the center of the substrate W are detected by the optical sensor, and the substrate W is transferred to the fork 230 such that the center position of the substrate W and the direction of the notch are set to a predetermined position and a predetermined direction. As a result, the transfer position of the substrate W is adjusted such that the center position of the substrate W and the direction of the notch in the LLM 14 are set to a predetermined position and a predetermined direction. Additionally, the MTP 18 is provided immediately below the aligner 17 and can temporarily retract the substrate W.

The buffer chamber 19 is disposed between the VTM 11a and the VTM 11b. The buffer chamber 19 has a cylindrical stage 190 in order to transfer the substrate W between the VTM 11a and the VTM 11b. The stage 190 has three lift pins 191 in the shape of a thin rod that can protrude from the upper surface. The lift pins 191 are disposed on the same circumference when viewed from the plane. Each lift pin 191 supports and lifts the substrate W by protruding from the upper surface of the stage 190. Additionally, each lift pin 191 mounts the supporting substrate W on the stage 190 by being retracted into the stage 190.

The substrate processing system 1 has the control device 100. The control device 100 controls the operation of the substrate processing system 1. For example, the control device 100 controls the operations of the robot arms 12 and 150, opening and closing of the gate valves 142 and 143, lifting and lowering of each lift pin 141 of the LLM 14, and lifting and lowering of each lift pin 191 of the buffer chamber 19. The control device 100 is, for example, a computer and includes a central processing unit (CPU), a random access memory (RAM), a read only memory (ROM), an auxiliary storage device, etc. The CPU operates based on a program stored in the ROM or the auxiliary storage device and controls the operation of each component of the substrate processing system 1. In the present embodiment, the control device 100 corresponds to a controller of the present disclosure.

### [Configuration of Robot Arms 12 and 150]

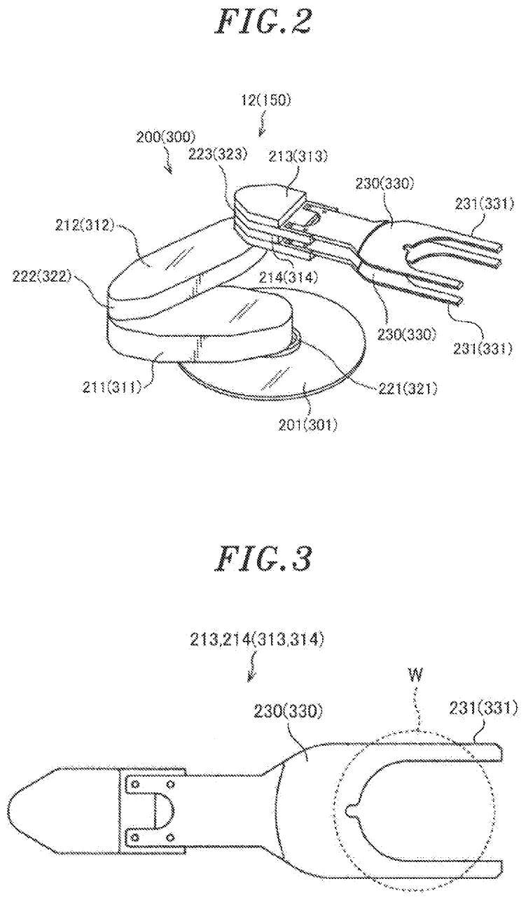

Next, an example of the configuration of the robot arms 12 and 150 according to the embodiment will be described. In the present embodiment, an example of a case where the robot arms 12 (12a and 12b) and 150 are articulated robots having the same configuration will be described. Hereinafter, as an example, the configuration of the robot arm 12 will be described. FIG. 2 is a perspective view showing an example of the configuration of the robot arm 12 according to the embodiment. In FIG. 2, parts constituting the robot arm 12 are denoted by numerals 200. In addition, in FIG. 2, parts constituting the robot arm 150 are denoted by numerals 300 indicated in parentheses.

The robot arm 12 has an arm part 200 and a base part 201. The base part 201 supports the arm part 200. The arm part 200 is rotatably mounted on the base part 201.

The arm part 200 is composed of a multi-joint arm in which a plurality of arms is connected by joints. The arm part 200 according to the embodiment includes a first arm 211, a second arm 212, and third arms 213 and 214.

One end of the first arm 211 is mounted on the base part 201. The base part 201 is provided with a first joint 221 that rotatably supports the first arm 211. One end of the second arm 212 is attached to the other end of the first arm 211. A second joint 222 that rotatably supports the second arm 212 is provided at the other end of the first arm 211. One end of the third arm 213 is attached to the other end of the second arm 212. A third joint 223 that rotatably supports the third arm 213 is provided at the other end of the second arm 212.

The robot arm 12 according to the embodiment is provided with the two third arms 213 and 214 at the distal end, and the third arms 213 and 214 are superposed on the third joint 223 such that one end thereof is supported by the third joint 223. Hereinafter, among the two third arms 213 and 214, the upper third arm 213 is referred to as the upper arm 213, and the lower third arm 214 is referred to as the lower arm 214. The robot arm 12 allows the upper arm 213 and the lower arm 214 to individually rotate through the third joint 223.

Next, an example of the configuration of the third arms 213 and 214 according to the embodiment will be described. The third arms 213 and 214 have the same configuration. FIG. 3 is a plan view showing an example of the configuration of the third arms 213 and 214 according to the embodiment. In FIG. 3, parts constituting the third arms 213 and 214 of the robot arm 12 are denoted by numerals 200. In addition, in FIG. 3, parts constituting the third arms 313 and 314 of the robot arm 150 are denoted by numerals 300 indicated in parentheses.

The fork 230 is provided in the third arms 213 and 214 (upper arm 213 and lower arm 214). The fork 230 has a Y-shape with its distal end divided into two support portions 231, and supports the substrate W. The robot arm 12 supports the substrate W using the fork 230 and transfers the substrate W.

As described above, the robot arm 150 has the same configuration as the robot arm 12. In describing the robot arm 150 below, the operation will be described using numerals 300 indicated in parentheses in FIGS. 2 and 3.

Additionally, the configuration of the robot arms 12 and 150 is an example and is not limited thereto. The robot arms 12a and 12b may be capable of transferring the substrate W between the PM 13, the LLM 14, and the buffer chamber 19, and are not limited to the configuration shown in FIGS. 1 to 3. In addition, the robot arm 150 may be capable of transferring the substrate W between the LLM 14, the EFEM 15, and the LP 16, and is not limited to the configuration shown in FIGS. 1 to 3.

### [Configuration of LLM 14]

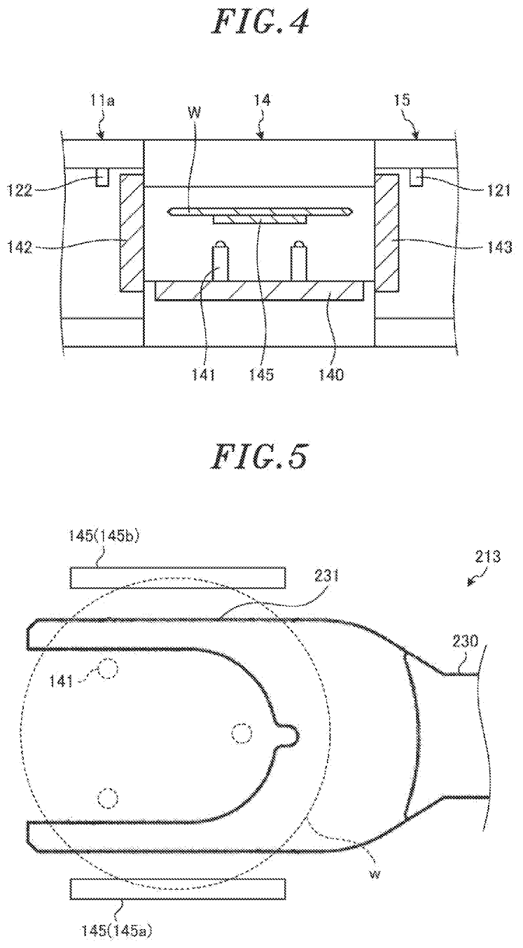

Next, an example of the configuration of the LLM 14 according to the embodiment will be described. FIG. 4 is a cross-sectional view schematically showing an example of the configuration of the LLM 14 according to the embodiment. FIG. 5 is a plan view schematically showing an example of the configuration of the LLM 14 according to the embodiment. The LLM 14 is connected to the VTM 11a and the EFEM 15. The LLM 14 has the gate valve 142 provided at the connection portion between the LLM 14 and the VTM 11a, and the gate valve 143 provided at the connection portion between the LLM 14 and the EFEM 15. The LLM 14 can switch the inside thereof between a depressurized state and an atmospheric state by closing the gate valves 142 and 143 and depressurizing the inside.

The LLM 14 has the stage 140 provided inside thereof. The stage 140 has a cooling mechanism such as a flow path through which a coolant flows, and the substrate W placed on the stage 140 can be cooled thereby. The stage 140 is provided with three lift pins 141 that can move up and down to support the substrate W. Additionally, the LLM 14 has a mounting part 145 on which the substrate W can be mounted on the stage 140. FIG. 5 shows the fork 230 of the robot arm 12 and shows an example of the positional relationship between the three lift pins 141 and the mounting part 145.

The three lift pins 141 are provided such that they are able to pass between the two support portions 231 of the fork 230 of the robot arm 12. Additionally, the three lift pins 141 are provided such that they can pass between the two support portions 331 of the fork 330 in the robot arm 150. For example, the three lift pins 141 are provided on the same circumference near the center of the stage 140. The three lift pins 141 are provided in a narrower range than the inside of the two support portions 231 of the fork 230 and the inside of the two support portions 331 of the fork 330. The LLM 14 supports the substrate W by lifting the three lift pins 141.

The mounting part 145 supports the substrate W by contacting a portion of the substrate W. In the LLM 14 according to the embodiment, two mounting parts 145a and 145b are provided having a gap therebetween in a direction crossing the direction of the gate valves 142 and 143 through which the substrate W passes. The gap between the mounting parts 145a and 145b is narrower than the width of the substrate W and greater than the width of the fork 230 of the robot arm 12 and the width of the fork 330 of the robot arm 150. The mounting parts 145a and 145b contact the edges of the substrate W mounted thereon and support the substrate W.

### [Configuration of Buffer Chamber 19]

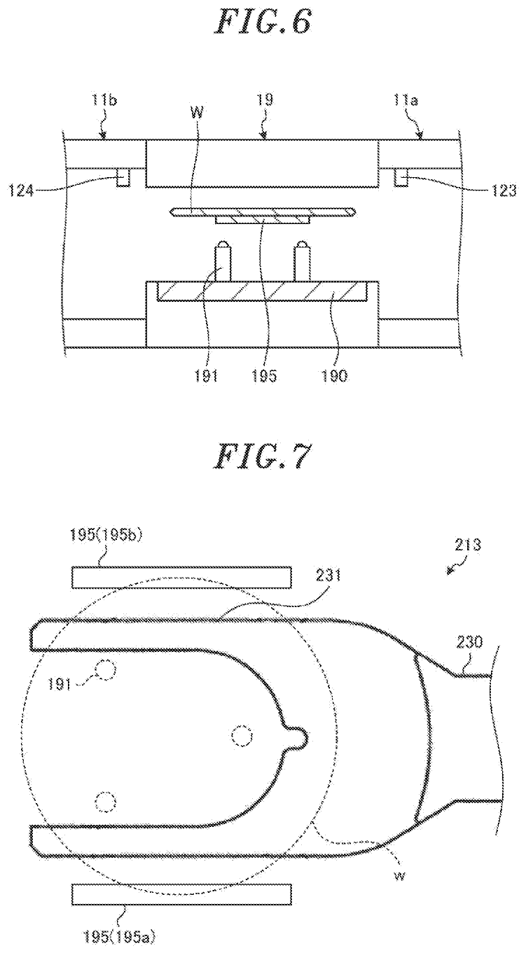

Next, an example of the configuration of the buffer chamber 19 according to the embodiment will be described. FIG. 6 is a cross-sectional view schematically showing an example of the configuration of the buffer chamber 19 according to the embodiment. FIG. 7 is a plan view schematically showing an example of the configuration of the buffer chamber 19 according to the embodiment. The buffer chamber 19 is connected to the VTM 11a and the VTM 11b.

The stage 190 is provided inside the buffer chamber 19. The stage 190 is provided with three lift pins 191 that can move up and down to support the substrate W. Additionally, the buffer chamber 19 is provided with a mounting part 195 on which the substrate W can be mounted on the stage 140. FIG. 7 shows the fork 230 of the robot arm 12 and shows an example of the positional relationship between the three lift pins 191 and the mounting part 195.

The three lift pins 191 are provided such that they are able to pass between the two support portions 231 of the fork 230 of the robot arm 12. For example, the three lift pins 191 are provided on the same circumference near the center of the stage 190. The three lift pins 191 are provided in a narrower range than the inside of the two support portions 231 of the fork 230. The buffer chamber 19 supports the substrate W by lifting the three lift pins 191.

In addition, the buffer chamber 19 is provided with the mounting part 195 on which the substrate W can be mounted on the stage 140. The mounting part 195 supports the substrate W by contacting a portion of the substrate W. In the buffer chamber 19 according to the embodiment, two mounting parts 195a and 195b are provided having a gap therebetween in a direction crossing the direction in which the substrate W passes. The gap between the mounting parts 195a and 195b is narrower than the width of the substrate W and greater than the width of the fork 230 of the robot arm 12. The mounting parts 195a and 195b contact the edges of the substrate W mounted thereon and support the substrate W.

Under the control of the control device 100, the substrate processing system 1 unloads an unprocessed substrate W1 from the FOUP using the robot arms 12 and 150, and transfers the substrate W1 to any one of the PMs 13 through the EFEM 15, the LLM 14, the VTMs 11a and 11b, and the buffer chamber 19. Furthermore, the substrate processing system 1 transfers the substrate W processed in the PM 13 to the FOUP using the robot arms 12 and 150 through the VTMs 11a and 11b, the buffer chamber 19, the LLM 14, and the EFEM 15 under the control of the control device 100.

The substrate processing system 1 according to the embodiment transfers the unprocessed substrate W1 and a processed substrate W2 in the LLM 14 and the buffer chamber 19 as follows under the control of the control device 100.

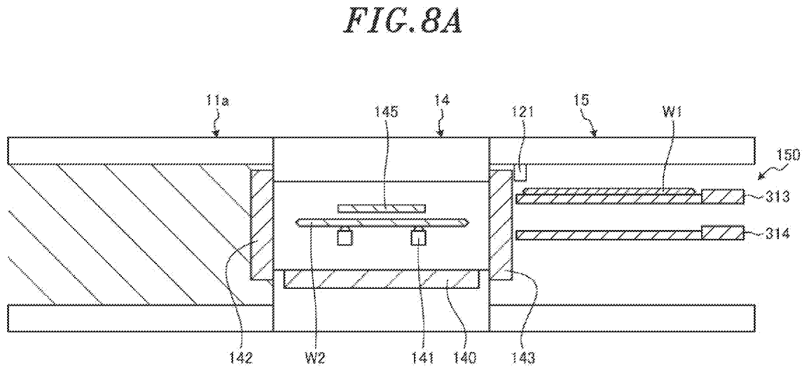

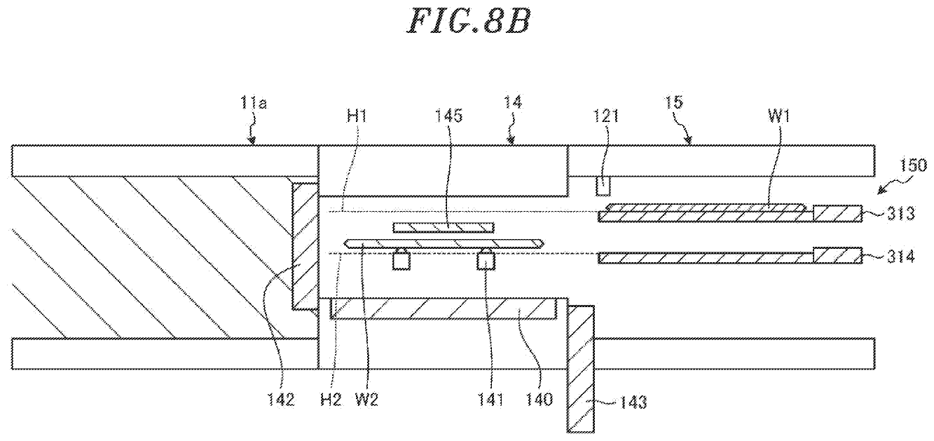

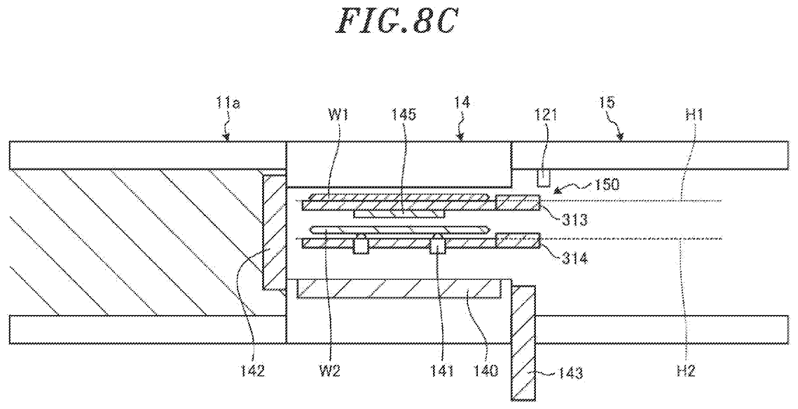

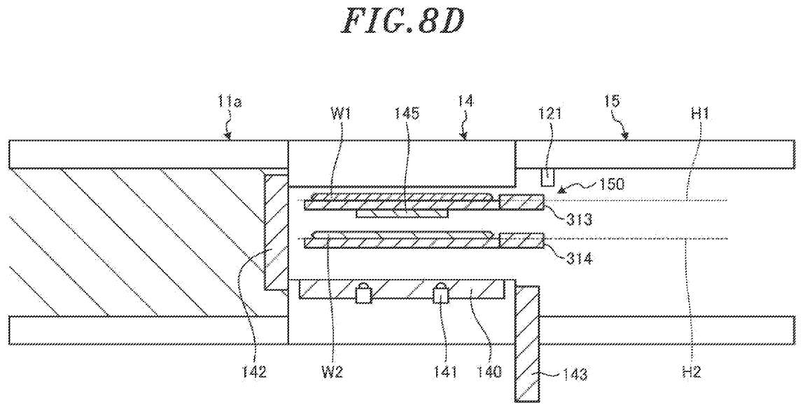

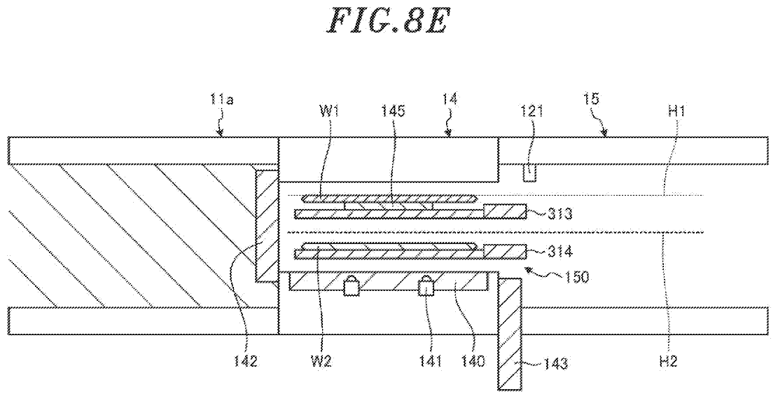

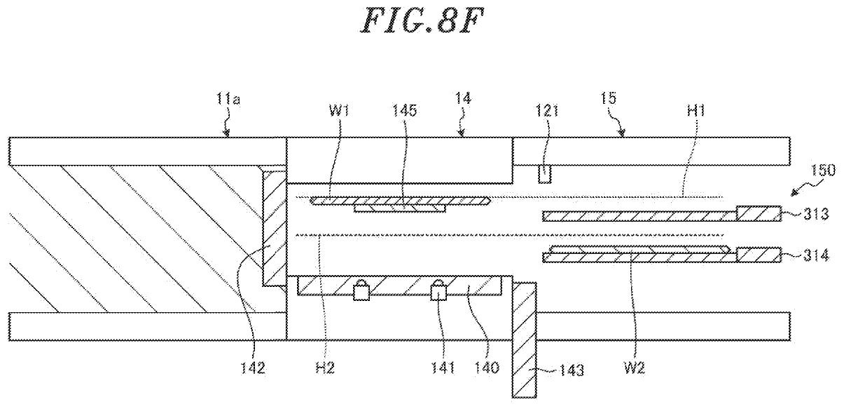

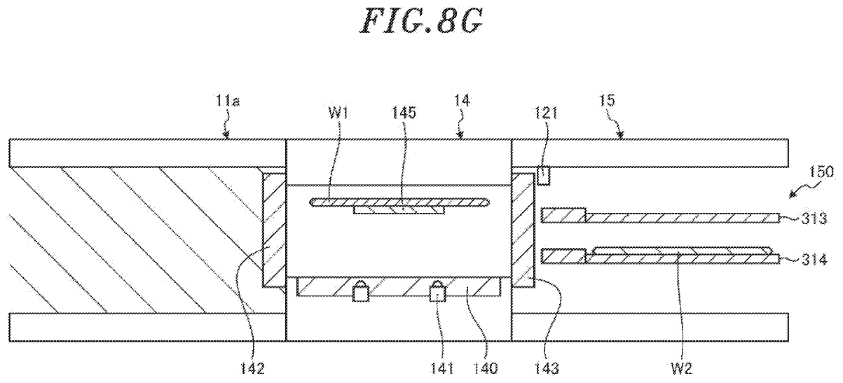

First, the flow of transferring the unprocessed substrate W1 and the processed substrate W2 in the LLM 14 will be described. FIGS. 8A to 8G are diagrams illustrating the flow of transfer in the LLM 14 in the substrate processing system 1 according to the embodiment. FIGS. 8A to 8G show the flow of transfer of the unprocessed substrate W1 and the processed substrate W2 between the LLM 14 and the EFEM 15. Additionally, FIGS. 8A to 8G schematically show only the tips of the lift pins 141. Further, in FIGS. 8A to 8G, in a case where the inside of the VTM 11a and the inside of the LLM 14 are in a depressurized state, the inside of the VTM 11a and the LLM 14 is indicated by a hatching pattern.

In FIG. 8A, the LLM 14 lifts the lift pins 141 to support the processed substrate W2. The lift pins 141 have been lifted to a height at which the gap between the lower surface of the processed substrate W2 supported by the lift pins 141 and the upper surface of the mounting part 145 is less than the gap between the upper arm 313 and lower arm 314 of the robot arm 150. The LLM 14 closes the gate valves 142 and 143 to switch the inside to an atmospheric state. The inside of the VTM 11a is in a predetermined depressurized state. The inside of the EFEM 15 is at atmospheric pressure. In the EFEM 15, the unprocessed substrate W1 is unloaded from the FOUP mounted on the LP 16, and the unprocessed substrate W1 is supported by the upper arm 313 of the robot arm 150.

When the inside of the LLM 14 is in an atmospheric state, the gate valve 143 is opened, as shown in FIG. 8B. The robot arm 150 causes the upper arm 313 and the lower arm 314 to enter the LLM 14, as shown in FIG. 8C. The robot arm 150 causes the upper arm 313 and the lower arm 314 to enter the LLM 14 at a height at which the upper surface of the upper arm 313 is higher than the upper surface of the mounting part 145 and the upper surface of the lower arm 314 is lower than the lower surface of the processed substrate W2 supported by the lift pins 141. In FIGS. 8B to 8F, the heights of the upper surfaces of the upper arm 313 and lower arm 314 of the robot arm 150 when the upper arm 131 and the lower arm 314 enter the LLM 14 are indicated by lines H1 and H2.

When the upper arm 313 and the lower arm 314 enter the LLM 14, the unprocessed substrate W1 passes through the detection area of the sensor 121. The sensor 121 outputs sensing information to the control device 100. The control device 100 identifies the position of the unprocessed substrate W1 disposed on the upper arm 313 on the basis of the sensing information obtained from the sensor 121 and position information of the upper arm 313 of the robot arm 150. The position information of the upper arm 313 of the robot arm 150 is identified on the basis of, for example, the length of each arm and the angle of each joint of the robot arm 150, and the like. The robot arm 150 transfers the unprocessed substrate W1 on the upper arm 313 to a position above a predetermined placement position with respect to the mounting part 145.

As shown in FIG. 8D, the LLM 14 lowers the lift pins 141 to place the processed substrate W2 supported by the lift pins 141 on the lower arm 314. As shown in FIG. 8E, the robot arm 150 lowers the upper arm 313 and the lower arm 314 to place the unprocessed substrate W1 supported by the upper arm 313 on the mounting part 145.

In this manner, the substrate processing system 1 according to the embodiment can cause the upper arm 313 and the lower arm 314 of the robot arm 150 to enter the LLM 14 once, thereby exchanging the unprocessed substrate W1 and the processed substrate W2. In addition, the robot arm 150 transfers the unprocessed substrate W1 to a predetermined placement position with respect to the mounting part 145 on the basis of sensing information obtained from the sensor 121, and the like when the upper arm 313 and the lower arm 314 enter the LLM 14. As a result, the amount of misalignment of the unprocessed substrate W1 with respect to the mounting part 145 from the predetermined placement position can be reduced.

After mounting the unprocessed substrate W1 on the mounting part 145, the robot arm 150 retracts the upper arm 313 and the lower arm 314 from the LLM 14, as shown in FIG. 8F. After the upper arm 313 and the lower arm 314 are retracted, the gate valve 143 is closed. The inside of the LLM 14 is depressurized. As shown in FIG. 8G, the robot arm 150 transfers the processed substrate W2 supported by the lower arm 314 to the FOUP mounted on the LP 16.

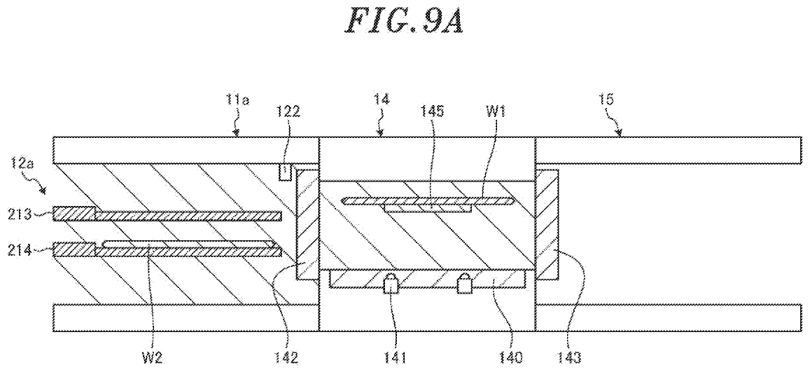

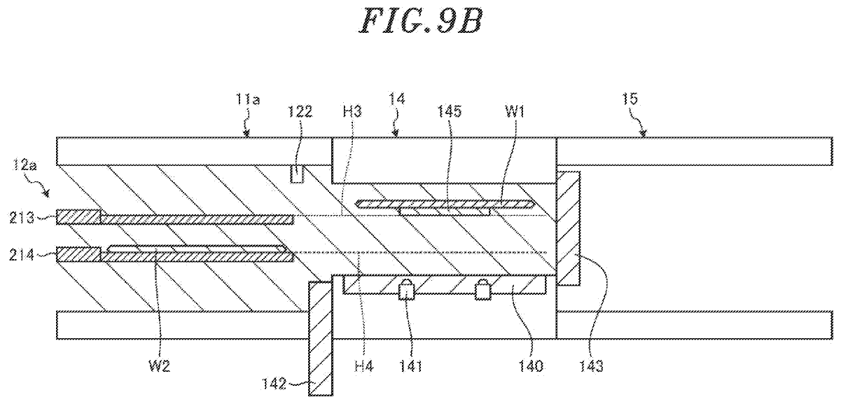

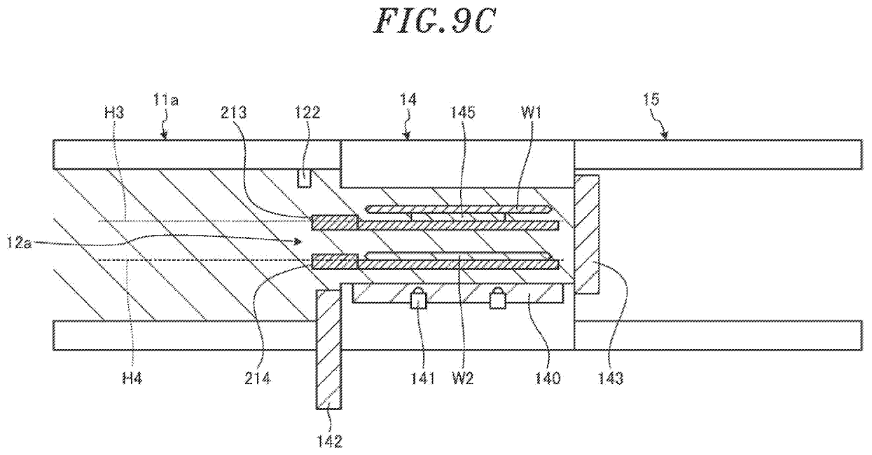

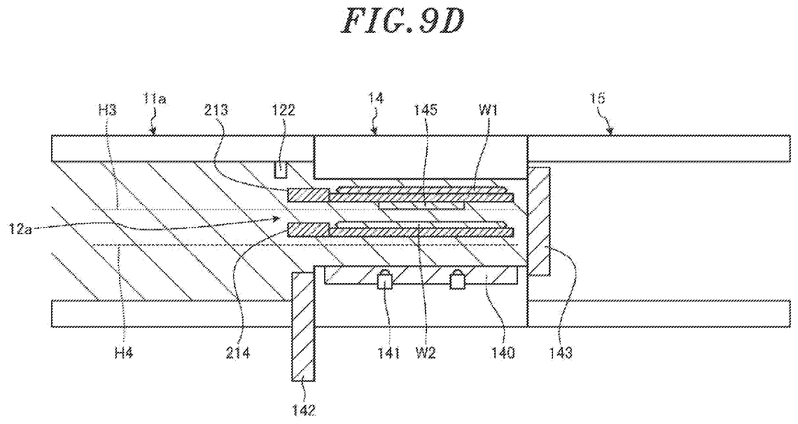

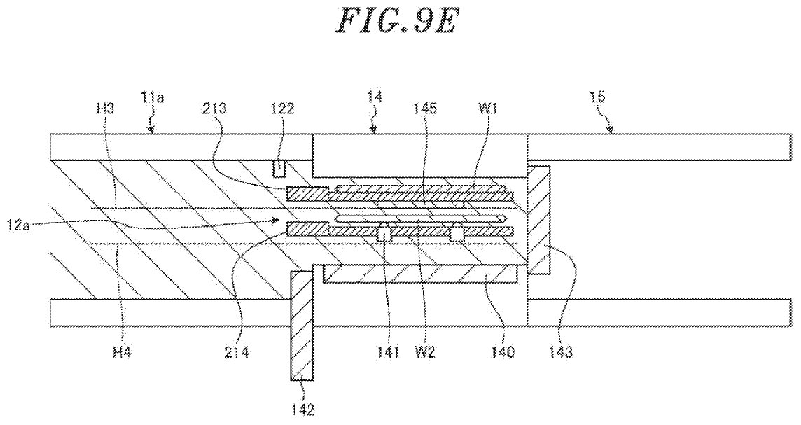

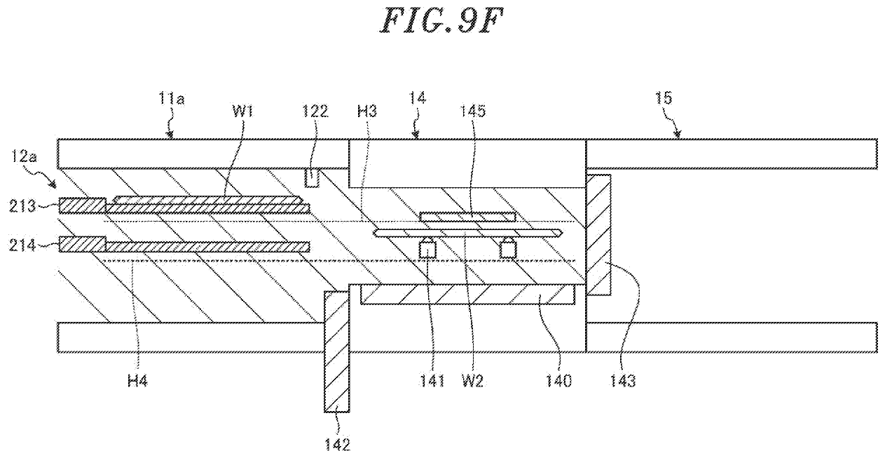

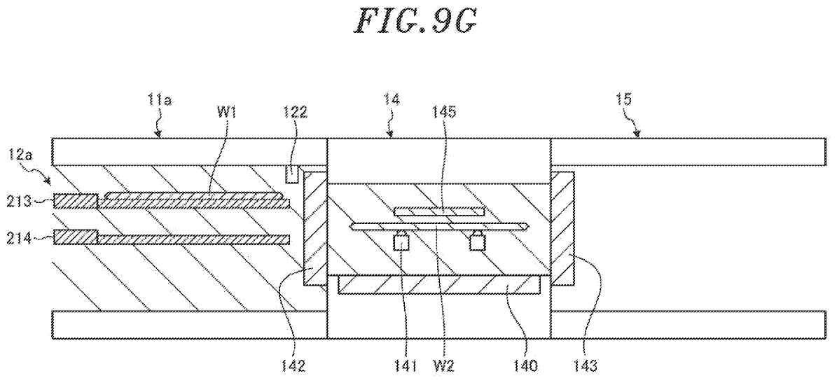

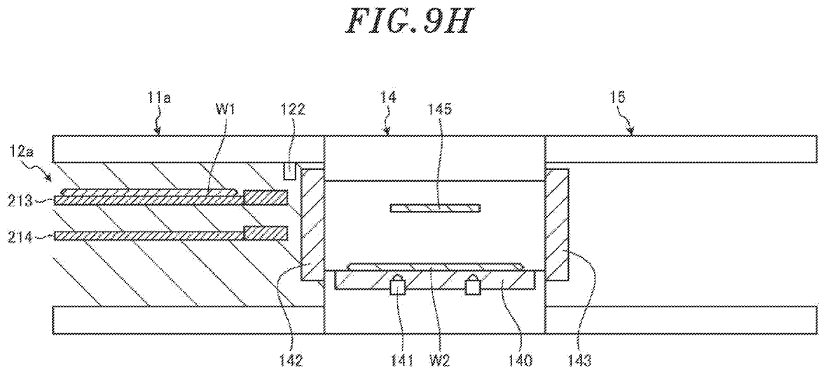

FIGS. 9A to 9H are diagrams illustrating a flow of transfer in the LLM 14 in the substrate processing system 1 according to the embodiment. FIGS. 9A to 9H show the flow of transfer of the unprocessed substrate W1 and the processed substrate W2 between the LLM 14 and the VTM 11a. Additionally, FIGS. 9A to 9H schematically show only the tips of the lift pins 141. Additionally, in FIGS. 9A to 9H, when the inside of the VTM 11a and the inside of the LLM are in a depressurized state, the inside of the VTM 11a and the LLM 14 is indicated by a hatching pattern.

As shown in FIG. 9A, the LLM 14 is depressurized until the inside thereof reaches a predetermined depressurized state. The VTM 11a is depressurized and the inside thereof is in a predetermined depressurized state. The processed substrate W2 is mounted on the lower arm 214 of the robot arm 12a.

When the inside of the LLM 14 is in a predetermined depressurized state, the gate valve 142 is opened, as shown in FIG. 9B. The robot arm 12a causes the upper arm 213 and the lower arm 214 to enter the LLM 14, as shown in FIG. 9C. The robot arm 12a causes the upper arm 213 and the lower arm 214 to enter the LLM 14 at a height at which the upper surface of the upper arm 213 is lower than the upper surface of the mounting part 145. In FIGS. 9B to 9F, the heights of the upper surfaces of the upper arm 213 and lower arm 214 of the robot arm 12a when they enter the LLM 14 are indicated by lines H3 and H4.

When the upper arm 213 and the lower arm 214 enter the LLM 14, the processed substrate W2 passes through the detection area of the sensor 122. The sensor 122 outputs sensing information to the control device 100. The control device 100 identifies the position of the processed substrate W2 disposed on the lower arm 214 on the basis of the sensing information obtained from the sensor 122 and position information of the lower arm 214 of the robot arm 12a. The position information of the lower arm 214 of the robot arm 12a is identified on the basis of, for example, the length of each arm and the angle of each joint of the robot arm 12a, and the like. The robot arm 12a transfers the processed substrate W2 on the lower arm 214 to a position above a predetermined placement position with respect to the lift pins 141.

As shown in FIG. 9D, the robot arm 12a raises the upper arm 213 and the lower arm 214 to lift the unprocessed substrate W1 mounted on the mounting part 145 by the upper arm 213, and supports the unprocessed substrate W1. As shown in FIG. 9E, the LLM 14 raises the lift pins 141 to lift and support the processed substrate W2 supported by the lower arm 214 with the lift pins 141.

In this manner, the substrate processing system 1 according to the embodiment can cause the upper arm 213 and the lower arm 214 of the robot arm 12a to enter the LLM 14 once, thereby exchanging the unprocessed substrate W1 and the processed substrate W2. Additionally, the robot arm 12a transfers the processed substrate W2 to a predetermined placement position with respect to the lift pins 141 on the basis of sensing information obtained from the sensor 122 when the upper arm 213 and the lower arm 214 enter the LLM 14. As a result, the amount of misalignment of the processed substrate W2 from the predetermined placement position with respect to the lift pins 141 can be reduced.

After supporting the unprocessed substrate W1 with the upper arm 213, the robot arm 12a retracts the upper arm 213 and the lower arm 214 from the LLM 14, as shown in FIG. 9F. After the upper arm 213 and the lower arm 214 are retracted, the gate valve 142 is closed. As shown in FIG. 9G, the robot arm 12a transfers the unprocessed substrate W1 supported by the upper arm 213 to the PM 13 or the buffer chamber 19 in which substrates are processed. As shown in FIG. 9H, the LLM 14 switches the inside thereof to an atmospheric state, lowers the lift pins 141, mounts the processed substrate W2 on the stage 140, and cools the processed substrate W2 by the stage 140.

Thereafter, the LLM 14 and the EFEM 15 perform transfer through the flow of FIGS. 8A to 8G described above, and exchange the processed substrate W2 with the next unprocessed substrate W1.

The position of the processed substrate W2 may be misaligned during substrate processing in the PM 13 or during transfer to the robot arm 12, and thus the position thereof on the lower arm 214 may be misaligned.

In the substrate processing system 1, the control device 100 identifies the placement position of the processed substrate W2 on the lower arm 214 on the basis of sensing information obtained from the sensor 122, and the like. The robot arm 12a transfers the processed substrate W2 to a position above a predetermined placement position with respect to the lift pins 141. For this reason, when the placement position of the processed substrate W2 on the lower arm 214 is misaligned, for example, the positions of the upper arm 213 and the lower arm 214 when the robot arm 12a transfers the substrate W2 on the lift pins 141 are deviated by the amount of misalignment. In this state, when the robot arm 12a raises the upper arm 213 and the lower arm 214 as shown in FIG. 9D, the placement position of the unprocessed substrate W1 on the upper arm 213 is misaligned. If the placement position of the unprocessed substrate W1 on the upper arm 213 is misaligned, the unprocessed substrate W1 may collide with members (e.g., gate valves 142, 143) around the transfer path when the unprocessed substrate W1 is transferred or there is a risk of misalignment of the placement position at the transfer destination.

Therefore, the substrate processing system 1 corrects the positional misalignment when exchanging the unprocessed substrate W1 and the processed substrate W2 between the LLM 14 and the VTM 11a. For example, in FIG. 9C, the robot arm 12a moves the upper arm 213 to a position where there is no positional misalignment with respect to the unprocessed substrate W1 mounted on the mounting part 145. Then, as shown in FIG. 9D, the robot arm 12a raises the upper arm 213 and the lower arm 214, and lifts and supports the unprocessed substrate W1 mounted on the mounting part 145 with the upper arm 213.

The robot arm 12a moves the lower arm 214 according to the positional misalignment in a state in which the unprocessed substrate W1 is lifted to correct the position of the processed substrate W2 with respect to the lift pins 141. For example, the robot arm 12a corrects the position of the processed substrate W2 with respect to the lift pins 141 by moving the lower arm 214 by an amount corresponding to the positional misalignment. For example, the robot arm 12a transfers the processed substrate W2 on the lower arm 214 to a position above a predetermined placement position with respect to the lift pins 141. Thereafter, the LLM 14 raises the lift pins 141 to lift and support the processed substrate W2 with the lift pins 141, as shown in FIG. 9E.

Accordingly, the substrate processing system 1 can transfer the unprocessed substrate W1 and the processed substrate W2 without causing positional misalignment. As a result, the robot arms 12 and 150 can stably and accurately transfer the unprocessed substrate W1 and the processed substrate W2. Additionally, it is possible to prevent the unprocessed substrate W1 and the processed substrate S2 from coming into contact with the gate valves 142 and 143 when the robot arms 12 and 150 transfer the unprocessed substrate W1 and the processed substrate W2.

Additionally, when the placement position of the processed substrate W2 on the lower arm 214 is misaligned by more than an allowable value, the substrate processing system 1 may correct the positional alignment. The allowable value is determined depending on the amount of misalignment of the placement position of the substrate W allowed by the substrate processing system 1. For example, the allowable value sets the amount of misalignment of the placement position of the substrate W that is allowed by a transfer path or a transfer destination.

For example, in the substrate processing system 1, the control device 100 identifies the placement position of the processed substrate W2 on the lower arm 214 on the basis of sensing information obtained from the sensor 122, and the like. The control device 100 determines whether the identified placement position of the substrate W2 is misaligned by more than the allowable value. If the placement position of the substrate W2 is misaligned by more than the allowable value, the substrate processing system 1 corrects the positional misalignment when exchanging the unprocessed substrate W1 and the processed substrate W2. For example, the robot arm 12a moves the upper arm 213 to a position where there is no misalignment with respect to the unprocessed substrate W1 mounted on the mounting part 145 in FIG. 9C. Then, as shown in FIG. 9D, the robot arm 12a raises the upper arm 213 and the lower arm 214, and lifts and supports the unprocessed substrate W1 mounted on the mounting part 145 with the upper arm 213. The robot arm 12a moves the lower arm 214 according to the positional misalignment in a state in which the unprocessed substrate W1 is lifted to correct the position of the processed substrate W2 with respect to the lift pins 141. As shown in FIG. 9E, the LLM 14 raises the lift pins 141 to lift and support the processed substrate W2 with the lift pins 141. In this manner, the substrate transfer method for transferring a substrate while correcting a positional misalignment is hereinafter referred to as a first transfer method. By using the first transfer method, the substrate processing system 1 corrects the position of the substrate W2, which slightly increases the time required for substrate exchange, but the substrate processing system 1 can transfer the unprocessed substrate W1 and the processed substrate W2 without causing positional misalignment.

On the other hand, if the misalignment of the placement position of the processed substrate W2 on the lower arm 214 is less than the allowable value, the robot arm 12a moves the lower arm 214 to a position where there is no misalignment of the processed substrate W2 with respect to the lift pins 141 in FIG. 9C. Then, as shown in FIG. 9D, the robot arm 12a raises the upper arm 213 and the lower arm 214 and lifts and supports the unprocessed substrate W1 mounted on the mounting part 145 with the upper arm 213. The robot arm 12a maintains its posture while lifting the unprocessed substrate W1, and maintains the position of the lower fork without changing it. As shown in FIG. 9E, the LLM 14 raises the lift pins 141 to lift and support the processed substrate W2 with the lift pins 141. As a result, the substrate processing system 1 can rapidly transfer the unprocessed substrate W1 and the processed substrate W2 although a positional misalignment occurs in the placement position of the unprocessed substrate W1 on the upper arm 213.

Additionally, when the placement position of the processed substrate W2 on the lower arm 214 is misaligned, the substrate processing system 1 may correct the positional misalignment as follows. When the placement position of the processed substrate W2 on the lower arm 214 is misaligned, the robot arm 12a moves the upper arm 213 and the lower arm 214 according to the misalignment to correct the position of the processed substrate W2 with respect to the lift pins 141. For example, when the placement position of the processed substrate W2 on the lower arm 214 is misaligned by more than the allowable value, the robot arm 12a moves the upper arm 213 and the lower arm 214 to a position where the positional misalignment of the processed substrate W2 becomes less than the allowable value. For example, the robot arm 12a moves the upper arm 213 and the lower arm 214 such that the position of the midpoint of the positional misalignment of the processed substrate W on the lower arm 214 matches the position of a reference for placing the substrate W2 with respect to the lift pins 141. Specifically, the control device 100 obtains a line segment connecting the center position of the substrate W2 that is misaligned on the lower arm 214 and the center position of the substrate W2 having no positional misalignment. The robot arm 12a moves the upper arm 213 and the lower arm 214 such that one position on the line segment matches the reference position for placing the substrate W2 with respect to the lift pins 141. Then, as shown in FIG. 9D, the robot arm 12a raises the upper arm 213 and the lower arm 214, and lifts and supports the unprocessed substrate W1 mounted on the mounting part 145 with the upper arm 213. As shown in FIG. 9E, the LLM 14 raises the lift pins 141 to lift and support the processed substrate W2 supported by the lower arm 214 with the lift pins 141. In this manner, the substrate transfer method for transferring a substrate while correcting a positional misalignment is hereinafter referred to as a second transfer method. Although positional misalignment less than the allowable value occurs in the unprocessed substrate W1 and the processed substrate W2 in the case of the second transfer method, the substrates W1 and W2 can be rapidly exchanged.

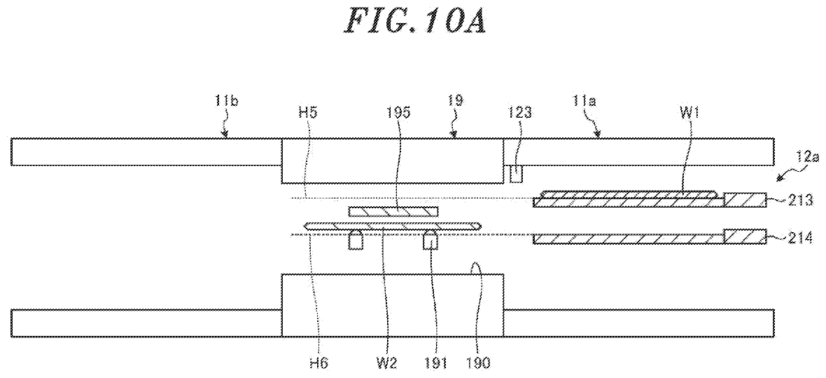

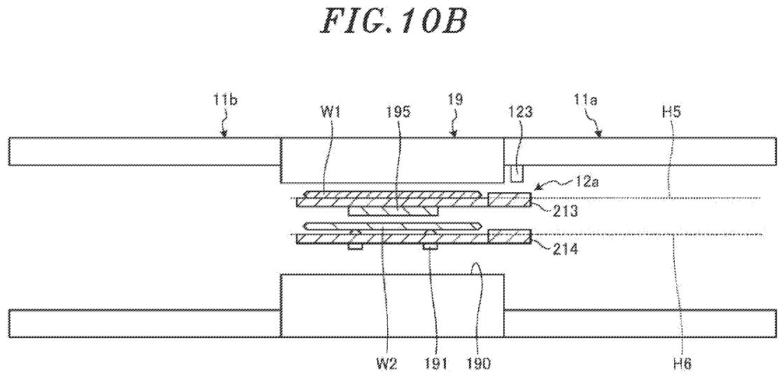

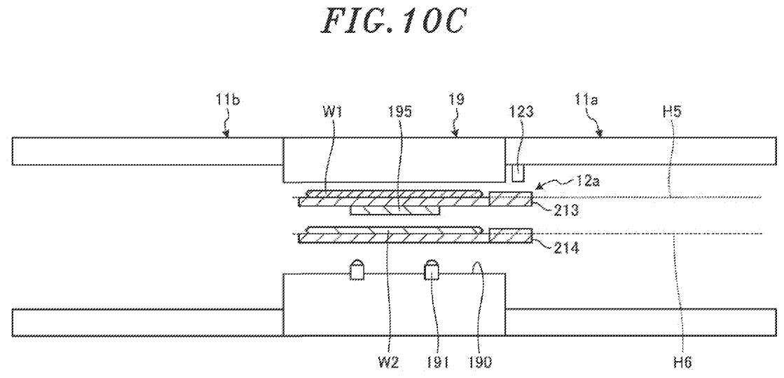

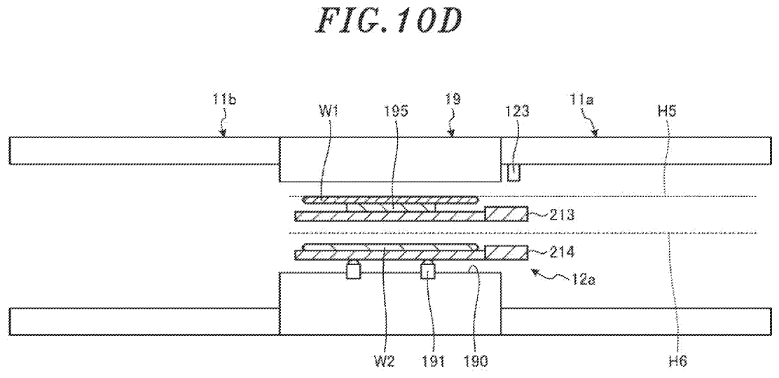

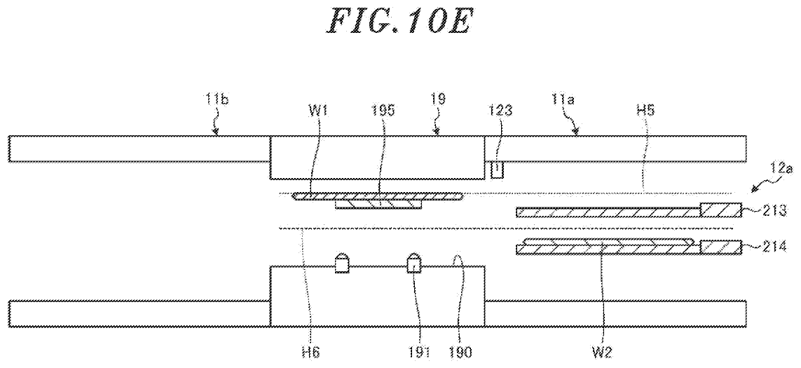

Next, the flow of transfer of the unprocessed substrate W1 and the processed substrate W2 in the buffer chamber 19 will be described. FIGS. 10A to 10E are diagrams illustrating the flow of transfer in the buffer chamber 19 in the substrate processing system 1 according to the embodiment. FIGS. 10A to 10E show the flow of transfer of the unprocessed substrate W1 and the processed substrate W2 between the buffer chamber 19 and the VTM 11a. Additionally, FIGS. 10A to 10E schematically show only the tips of the lift pins 191.

In FIG. 10A, the buffer chamber 19 raises the lift pins 191 to support the processed substrate W2. The lift pins 191 are raised to a height at which the gap between the lower surface of the processed substrate W2 and the upper surface of the mounting part 195 is less than the gap between the upper arm 213 and the lower arm 214 of the robot arm 12a. In the VTM 11a, the unprocessed substrate W1 is supported by the upper arm 213 of the robot arm 12a.

The robot arm 12a causes the upper arm 213 and the lower arm 214 to enter the buffer chamber 19, as shown in FIG. 10B. The robot arm 12a moves the upper arm 213 and the lower arm 214 into the buffer chamber 19 at a height at which the upper surface of the upper arm 213 is higher than the upper surface of the mounting part 195 and the upper surface of the lower arm 214 is lower than the lower surface of the processed substrate W2 supported by the lift pins 191. In FIGS. 10A to 10E, the heights of the upper surfaces of the upper arm 213 and the lower arm 214 of the robot arm 12a when entering the buffer chamber 19 are indicated by lines H5 and H6.

When the upper arm 213 and the lower arm 214 enter the buffer chamber 19, the unprocessed substrate W1 passes through the detection area of the sensor 123. The sensor 123 outputs sensing information to the control device 100. The control device 100 identifies the placement position of the unprocessed substrate W1 on the upper arm 213 on the basis of the sensing information obtained from the sensor 123 and position information of the upper arm 213 of the robot arm 12a. The position information of the upper arm 213 of the robot arm 12a is identified on the basis of the length of each arm and the angle of each joint of the robot arm 12a, and the like, for example. The robot arm 12a transfers the unprocessed substrate W1 on the upper arm 213 to a position above a predetermined placement position with respect to the mounting part 195.

As shown in FIG. 10C, the buffer chamber 19 lowers the lift pins 191 to place the processed substrate W2 supported by the lift pins 191 on the lower arm 214. As shown in FIG. 10D, the robot arm 12a lowers the upper arm 213 and the lower arm 214 to place the unprocessed substrate W1 supported by the upper arm 213 on the mounting part 195.

In this manner, the substrate processing system 1 according to the embodiment can exchange the unprocessed substrate W1 and the processed substrate W2 by causing the upper arm 213 and the lower arm 214 of the robot arm 12a to enter the buffer chamber 19 once.

After mounting the unprocessed substrate W1 on the mounting part 195, the robot arm 12a retracts the upper arm 213 and the lower arm 214 from the buffer chamber 19, as shown in FIG. 10E.

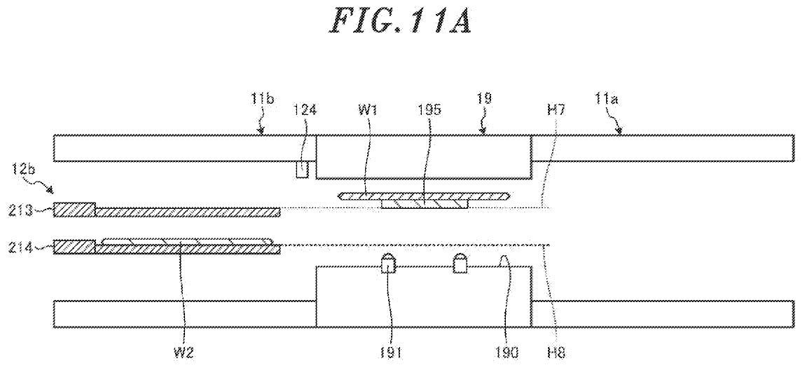

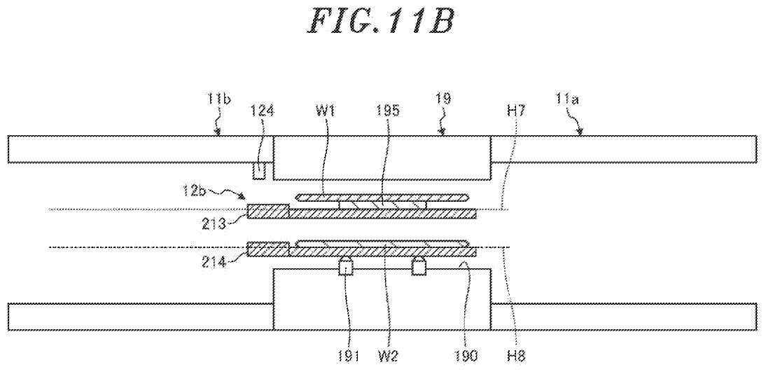

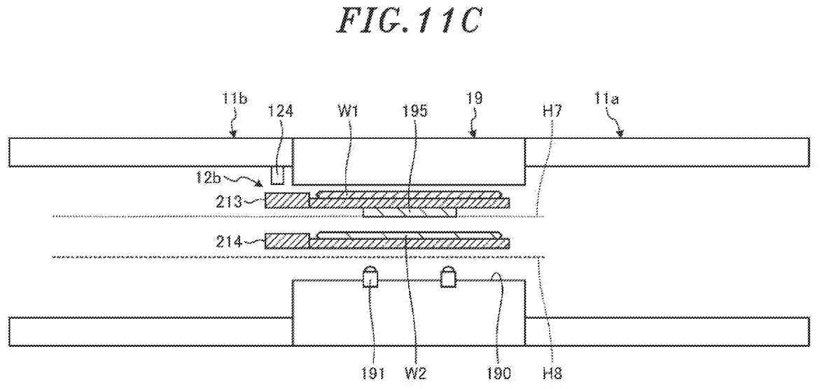

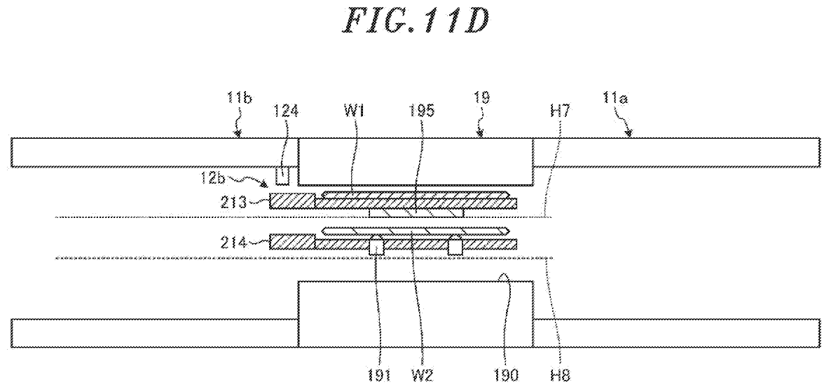

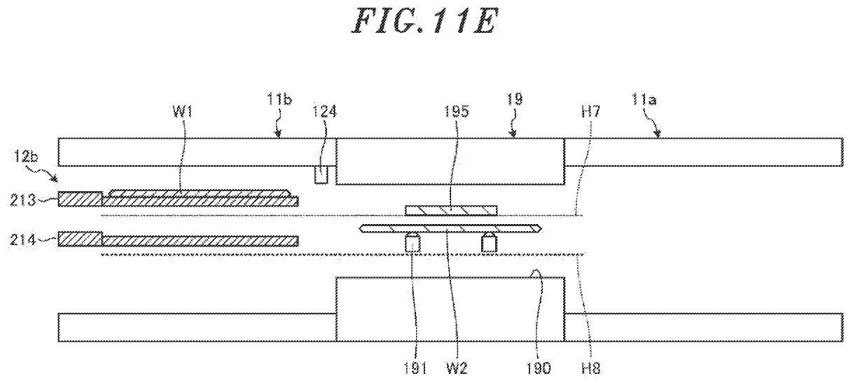

FIGS. 11A to 11E are diagrams illustrating a flow of transfer in the buffer chamber 19 in the substrate processing system 1 according to the embodiment. FIGS. 11A to 11E show the flow of transfer of the unprocessed substrate W1 and the processed substrate W2 between the buffer chamber 19 and the VTM 11b. Additionally, FIGS. 11A to 11E schematically show only the tips of the lift pins 191.

In the buffer chamber 19, as shown in FIG. 11A, the unprocessed substrate W1 is mounted on the mounting part 195. The processed substrate W2 is mounted on the lower arm 214 of the robot arm 12b.

The robot arm 12b causes the upper arm 213 and the lower arm 214 to enter the buffer chamber 19, as shown in FIG. 11B. The robot arm 12b causes the upper arm 213 and the lower arm 214 to enter the buffer chamber 19 at a height where the upper surface of the upper arm 213 is lower than the upper surface of the mounting part 195. In FIGS. 11A to 11E, the heights of the upper surfaces of the upper arm 213 and the lower arm 214 of the robot arm 12b when entering the buffer chamber 19 are indicated by lines H7 and H8.

When the upper arm 213 and the lower arm 214 enter the buffer chamber 19, the processed substrate W2 passes through the detection area of the sensor 124. The sensor 124 outputs sensing information to the control device 100. The control device 100 identifies the placement position of the processed substrate W2 on the lower arm 214 on the basis of the sensing information obtained from the sensor 124 and position information of the lower arm 214 of the robot arm 12b. The position information of the lower arm 214 of the robot arm 12b is identified on the basis of the length of each arm and the angle of each joint of the robot arm 12b, and the like, for example. The robot arm 12b transfers the processed substrate W2 on the lower arm 214 to a position above a predetermined placement position with respect to the lift pins 191.

As shown in FIG. 11C, the robot arm 12b raises the upper arm 213 and the lower arm 214, and lifts and supports the unprocessed substrate W1 mounted on the mounting part 195 with the upper arm 213. As shown in FIG. 11D, in the buffer chamber 19, the lift pins 191 are raised to lift and support the processed substrate W2 supported by the lower arm 214 with the lift pins 191.

In this manner, the substrate processing system 1 according to the embodiment can exchange the unprocessed substrate W1 and the processed substrate W2 by causing the upper arm 213 and the lower arm 214 of the robot arm 12b to enter the buffer chamber 19 once.

After supporting the unprocessed substrate W1 processing with the upper arm 213, the robot arm 12b retracts the upper arm 213 and the lower arm 214 from the buffer chamber 19, as shown in FIG. 11E. The robot arm 12b transfers the unprocessed substrate W1 supported by the upper arm 213 to the PM 13 that performs substrate processing to process the substrate. The buffer chamber 19 and the TM 11a perform transfer in the flow shown in FIGS. 10A to 10E described above, and exchange the processed substrate W2 with the next unprocessed substrate W1.

However, as described above, there are cases in which positional misalignment occurs in the processed substrate W2 during substrate processing in the PM 13 or during transfer to the robot arm 12, and thus the position of the processed substrate W2 on the lower arm 214 is misaligned. The substrate processing system 1 may correct positional misalignment when exchanging the unprocessed substrate W1 and the processed substrate W2 between the buffer chamber 19 and the VTM 11b as in the case of exchanging the substrates W1 and W2 between the LLM 14 and the VTM 11a as described above.

### [Substrate Transfer Method]

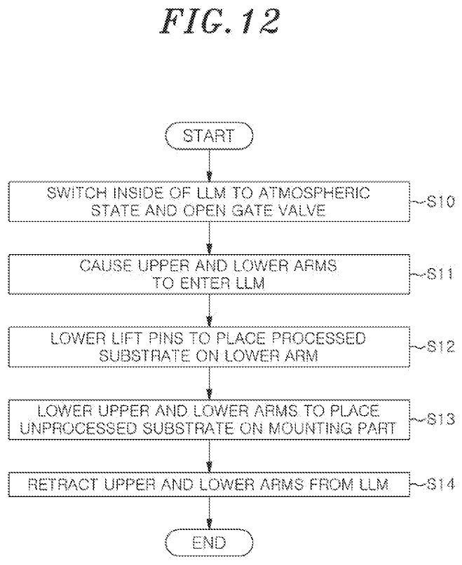

Next, the processing flow of the substrate transfer method according to the present embodiment will be described. FIG. 12 is a flowchart showing an example of the processing flow of the substrate transfer method according to the embodiment. In FIG. 12, an example of a case in which the unprocessed substrate W1 and the processed substrate W2 are transferred between the LLM 14 and the EFEM 15, as shown in FIGS. 8A to 8G, will be described.

In the LLM 14, the lift pins 141 are lifted to support the processed substrate W2. The robot arm 150 supports the unprocessed substrate W1 with the upper arm 313.

The control device 100 controls the LLM 14 and the gate valve 143 to switch the inside of the LLM 14 to an atmospheric state and open the gate valve 143 (step S10).

The control device 100 controls the robot arm 150 such that the upper arm 313 and the lower arm 314 enter the LLM 14 (step S11). When the upper arm 313 and the lower arm 314 enter the LLM 14, the sensor 121 outputs sensing information to the control device 100. The control device 100 identifies the placement position of the unprocessed substrate W1 on the upper arm 313 on the basis of the sensing information obtained from the sensor 121 and position information of the upper arm 313 of the robot arm 150. The control device 100 controls the robot arm 150 to transfer the unprocessed substrate W1 on the upper arm 313 to a position above a predetermined placement position with respect to the mounting part 145.

The control device 100 controls the LLM 14 to lower the lift pins 141 such that the processed substrate W2 supported by the lift pins 141 is placed on the lower arm 314 (step S12). The control device 100 controls the robot arm 150 to lower the upper arm 313 and the lower arm 314 such that the unprocessed substrate W1 supported by the upper arm 313 is placed on the mounting part 145 (step S13).

The control device 100 controls the robot arm 150 to retract the upper arm 313 and the lower arm 314 from the LLM 14 (step S14) and ends processing.

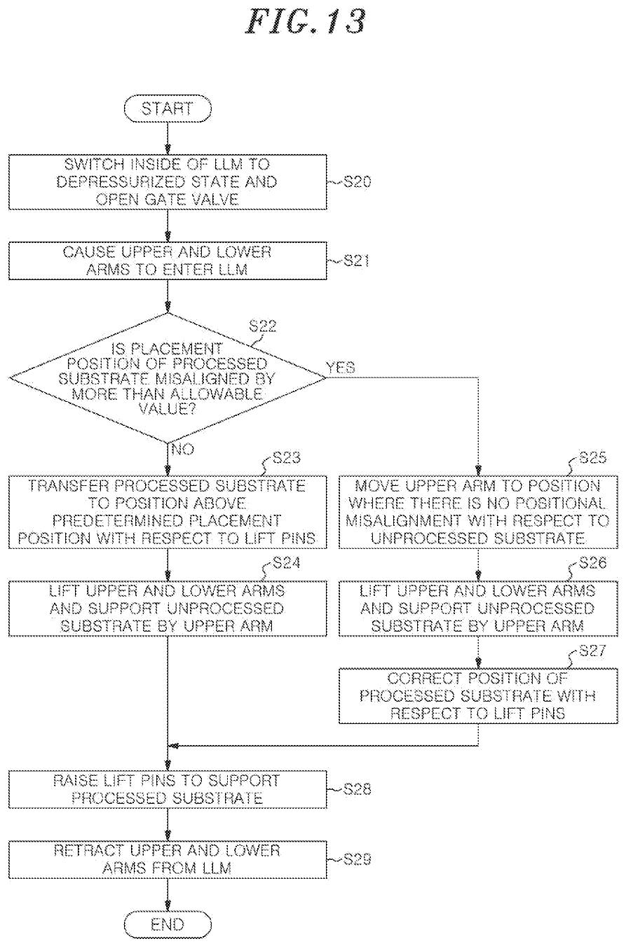

FIG. 13 is a flowchart showing an example of the processing flow of the substrate transfer method according to the embodiment. In FIG. 13, an example of a case in which the unprocessed substrate W1 and the processed substrate W2 are transferred between the LLM 14 and the VTM 11a, as shown in FIGS. 9A to 9H, will be described.

In the LLM 14, the unprocessed substrate W1 is mounted on the mounting part 145. The robot arm 12a supports the processed substrate W2 with the lower arm 214.

The control device 100 controls the LLM 14 and the gate valves 142 and 143 to depressurize the inside the LLM 14 with the gate valves 142 and 143 closed and switch the inside to a depressurized state, and opens the gate valve 142 when the LLM 14 is in a predetermined depressurized state (step S20).

The control device 100 controls the robot arm 12a such that the upper arm 213 and the lower arm 214 enter the LLM 14 (step S21). When the upper arm 213 and the lower arm 214 enter the LLM 14, the sensor 122 outputs sensing information to the control device 100. The control device 100 identifies the placement position of the processed substrate W2 on the lower arm 214 on the basis of the sensing information obtained from the sensor 122 and position information of the lower arm 214 of the robot arm 12a.

The control device 100 determines whether the placement position of the processed substrate W2 on the lower arm 214 is misaligned by more than an allowable value (step S22).

If the positional deviation is less than the allowable value (No in step S22), the control device 100 controls the robot arm 12a to transfer the processed substrate W2 on the lower arm 214 to a position above a predetermined placement position with respect to the lift pins 141 (step S23). The control device 100 controls the robot arm 12a to raise the upper arm 213 and the lower arm 214 and lifts and supports the unprocessed substrate W1 mounted on the mounting part 145 with the upper arm 213 (step S24).

On the other hand, if the positional misalignment is more than the allowable value (Yes in step S23), the control device 100 controls the robot arm 12a to move the upper arm 213 to a position where there is no positional misalignment with respect to the unprocessed substrate W1 mounted on the mounting part 145 (step S25). The control device 100 controls the robot arm 12a to raise the upper arm 213 and the lower arm 214, and lifts and supports the unprocessed substrate W1 mounted on the mounting part 145 with the upper arm 213 (step S26). Then, the control device 100 controls the robot arm 12a to move the lower arm 214 according to the positional misalignment in a state in which the unprocessed substrate W1 is lifted to correct the position of the processed substrate W2 with respect to the lift pins 141 (step S27). For example, the control device 100 controls the robot arm 12a to transfer the processed substrate W2 on the lower arm 214 to a position above a predetermined placement position with respect to the lift pins 141.

The control device 100 controls the LLM 14 to raise the lift pins 141 and lifts and supports the processed substrate W2 supported by the lower arm 214 using the lift pins 141 (step S28). The control device 100 controls the robot arm 12a to retract the upper arm 213 and the lower arm 214 from the LLM 14 (step S29) and ends processing.

As described above, in the substrate transfer method according to the embodiment, the robot arm 12 (transfer mechanism) in a state in which the substrate W2 (second substrate) is supported by the lower arm 214 (lower fork) enters the LLM 14 and the buffer chamber 19 in which the substrate W1 (first substrate) is mounted on the mounting parts 145 and 195, and the substrate W1 mounted on the mounting parts 145 and 195 is lifted by the upper arm 213 (upper fork) (steps S21, S23, S24). In the substrate transfer method, the plurality of lift pins 141 and 191 are raised in a state in which the substrate W1 is lifted by the upper arm 213 to lift the substrate W2 supported by the lower arm 214 by the plurality of lift pins 141 and 191 (step S28). In the substrate transfer method, the robot arm 12 is retracted from the LLM 14 and the buffer chamber 19 in a state in which the substrate W2 is lifted by the plurality of lift pins 141 and 191 (step S29). Accordingly, the substrate transfer method according to the embodiment can reduce the time required to exchange the substrates W1 and W2.

In addition, in the substrate transfer method according to the embodiment, when the placement position of the substrate W2 on the lower arm 214 is misaligned, the robot arm 12 is moved to a position where there is no positional misalignment with respect to the substrate W1 mounted on the mounting part 145 and 195, and then the substrate W1 is lifted by the upper arm 213 (steps S25 and S26). In the substrate transfer method, the robot arm 12 is moved according to the positional misalignment in a state in which the substrate W1 is lifted by the upper arm 213 to correct the position of the substrate W2 with respect to the plurality of lift pins 141 and 191, and then the plurality of lift pins 141 and 191 is lifted (steps S27 and S28). As a result, in the substrate transfer method according to the embodiment, the substrate W1 is not misaligned, positional misalignment of the substrate W2 can be corrected, and the substrates W1 and W2 can be exchanged.

In addition, in the substrate transfer method according to the embodiment, when the placement position of the substrate W2 on the lower arm 214 is misaligned by more than an allowable value, the robot arm 12 is moved to a position where there is no positional misalignment with respect to the substrate W1 mounted on the mounting part 145 and 195, and then the substrate W1 is lifted by the upper arm 213 (steps S25 and S26). In addition, in the substrate transfer method, the robot arm 12 is moved according to the positional misalignment in a state in which the substrate W1 is lifted by the upper arm 213 to correct the position of the substrate W2 with respect to the plurality of lift pins 141 and 191, and then the plurality of lift pins 141 and 191 is lifted (steps S27 and S28). On the other hand, in the substrate transfer method, when the positional misalignment of the substrate W2 on the lower arm 214 is less than the allowable value, the robot arm 12 is moved to a position where there is no positional misalignment of the substrate W2 on the lower arm 214 with respect to the plurality of lift pins 141 and 191, and then the substrate W1 is lifted by the upper arm 213 (steps S23 and S24). In the substrate transfer method, the plurality of lift pins 141 and 191 is lifted without changing the position of the lower arm 214 in a state in which the substrate W1 is lifted by the upper arm 213 (step S28). Accordingly, in the substrate transfer method according to the embodiment, when the placement position of the substrate W2 on the lower arm 214 is misaligned by more than the allowable value, the substrate W1 and the substrate W2 can be exchanged by correcting the positional misalignment of W2 without positional misalignment of the substrate W1. Additionally, when the placement position of the substrate W2 on the lower arm 214 is less than the allowable value, the substrate W1 and W2 can be rapidly exchanged.

In addition, in the substrate transfer method according to the embodiment, when the placement position of the substrate W2 on the lower arm 214 is misaligned by more than the allowable value, the robot arm 12 is moved by the amount of the positional misalignment to correct the position of the substrate W2 with respect to the plurality of lift pins 141 and 191 (step S27). As a result, in the substrate transfer method according to the embodiment, the positional misalignment of the substrate W2 can be corrected and the substrate W1 and the substrate W2 can be rapidly exchanged.

In addition, in the substrate transfer method according to the embodiment, when the placement position of the substrate W2 on the lower arm 214 is misaligned, the robot arm 12 is moved according to the positional misalignment to correct the position of the substrate W2 with respect to the lift pins 141 and 191, and then the substrate W1 mounted on the mounting part 145 and 195 is lifted by the upper arm 213. Accordingly, in the substrate transfer method according to the embodiment, a positional misalignment less than the original positional misalignment of the substrate W2 occurs in the substrate W1 and the substrate W2, but the substrate W1 and the substrate W2 can be rapidly exchanged.

In addition, in the substrate transfer method according to the embodiment, when the placement position of the substrate W2 on the lower arm 214 is misaligned by more than the allowable value, the robot arm 12 is moved to a position where the positional misalignment of the substrate W2 with respect to the lift pins 141 and 191 becomes less than the allowable value, and then the substrate W1 mounted on the mounting part 145 and 195 is lifted by the upper arm 213. As a result, in the substrate transfer method according to the embodiment, a positional misalignment less than the original positional misalignment of the substrate W2 occurs in the substrate W1 and the substrate W2, but the substrate W1 and the substrate W2 can be rapidly exchanged while reducing the positional misalignment.

In addition, in the substrate transfer method according to the embodiment, the robot arms 12 and 150 which support the substrate W1 with the upper arms 213 and 313 enter the LLM 14 and the buffer chambers 19 in which the substrate W2 is supported by the plurality of raised lift pins 141 and 191, the substrate W2 is mounted on the lower arms 214 and 314 by lowering the plurality of lift pins 141 and 191 (steps S11, S12). In the substrate transfer method, in a state in which the substrate W2 is mounted on the lower arms 214 and 314, the substrate W1 supported by the upper arms 213 and 313 is mounted on the mounting parts 145 and 195 (step S13). In the substrate transfer method, the robot arms 12 and 150 are retracted from the LLM 14 and the buffer chamber 19 in a state in which the substrate W2 is mounted on the lower arms 214 and 314 (step S14). Accordingly, the substrate transfer method according to the embodiment can reduce the time required to exchange the substrate W1 and the substrate W2.

In the substrate transfer method according to the embodiment, the substrate W1 is a substrate W that is not subjected to predetermined processing (for example, substrate processing), and the substrate W2 is a substrate on which the predetermined processing has been performed. Since the unprocessed substrate W1 is transferred above the processed substrate W2, particles that have fallen from the processed substrate W2 can be prevented from adhering to the unprocessed substrate W1.

Although the embodiment has been described above, it should be considered that the embodiment disclosed here is an example in all respects and is not restrictive. In fact, the above-described embodiment may be implemented in various forms. In addition, the above-described embodiment may be omitted, replaced, or changed in various forms without departing from the scope of the claims and the spirit thereof.

For example, in the above embodiment, an example of a case where the substrate W is a semiconductor wafer has been described. However, the substrate W is not limited thereto. The substrate may be any substrate such as a glass substrate.

In addition, in the above embodiment, an example of a case in which, when the placement position of the processed substrate W2 on the lower arm 214 is misaligned, the positional misalignment is corrected when the unprocessed substrate W1 and the processed substrate W2 are exchanged between the LLM 14 and the VTM 11a has been described. However, it is not limited thereto. When the placement position of the substrate W is misaligned, the substrate processing system 1 may transfer the misaligned substrate W to a temporary holding part provided in a vacant PM 13 or VTMs 11a and 11b, temporarily mount the substrate, perform alignment, and transfer the aligned substrate W. For example, when the placement position of the processed substrate W2 on the lower arm 214 is misaligned by more than an allowable value, the substrate processing system 1 may perform alignment of the substrate W2 and transfer the aligned substrate W2. The substrate transfer method for temporarily mounting a substrate, performing alignment, and transferring the aligned substrate in this manner is hereinafter referred to a third transfer method. Additionally, when the placement position of the processed substrate W2 on the lower arm 214 is misaligned by more than an allowable value, the substrate processing system 1 may individually transfer the unprocessed substrate W1 and the processed substrate W2 without exchanging the unprocessed substrate W1 and the processed substrate W2 through the above-described substrate transfer method in the LLM 14 and the buffer chamber 19. For example, the substrate processing system 1 may unload one of the substrate W1 and the substrate W2 from the LLM 14 and the buffer chamber 19 and then place the other therein. For example, the substrate processing system 1 may exchange the unprocessed substrate W1 and the processed substrate W2 by causing the robot arm 12a or the robot arm 150 to enter the LLM 14 twice, unloading one of the substrates W1 and W2 at the first entry, and then placing the other at the second entry. The substrate transfer method in which the robot arm 150 enters twice in this manner is hereinafter referred to as a fourth transfer method. The substrate processing system 1 may switch substrate transfer methods depending on the throughput required for transfer of the substrates W1 and W2 or an allowable amount of positional misalignment. For example, the substrate processing system 1 determines whether the placement position of the processed substrate W2 on the lower arm 214 is misaligned by more than an allowable value. When the positional misalignment is less than the allowable value, the substrate processing system 1 may exchange the unprocessed substrate W1 and the processed substrate W2 through the processing steps S23 and S24 of the substrate transfer method of FIG. 12 described above. Additionally, when the positional misalignment is greater than the allowable value, the substrate processing system 1 may select an appropriate substrate transfer method from the above-described first to fourth transfer methods on the basis of the amount of positional misalignment and an allowable transfer time and performs the selected method.

### DESCRIPTION OF REFERENCE NUMERALS

1: Substrate processing system
10: Processing system body
11, 11a, 11b: Vacuum transfer module (VTM)
12, 12a, 12b, 150: Robot arm
13: Process module (PM)
14: Load lock module (LLM)
15: EFEM
16: Load port (LP)
19: Buffer chamber
100: Control device
140, 190: Stage
141, 191: Lift pin
145, 145a, 145b, 195, 195a, 195b: Mounting part
200, 300: Arm part
211, 311: First arm
212, 312: Second arm
213, 313: Third arm, upper arm
214, 314: Third arm, lower arm
230, 330: Fork
231, 331: Support portion
W, W1, W2: Substrate

1. A substrate transfer method of a transfer device having a transfer chamber provided with a transfer mechanism having an upper fork and a lower fork, on an upper side and a lower side, capable of supporting a substrate, and a buffer chamber connected to the transfer chamber, the buffer chamber provided with a mounting part capable of mounting a substrate by contacting a portion of the substrate, and provided with a plurality of pins capable of supporting the substrate by being raised and lowered and provided below the mounting part, the substrate transfer method comprising:
a first process in which the transfer mechanism having a second substrate supported by the lower fork enters the buffer chamber in which a first substrate is mounted on the mounting part, and the first substrate mounted on the mounting part is lifted by the upper fork;
a second process in which the plurality of pins are raised in a state in which the first substrate is lifted by the upper fork to lift the second substrate supported by the lower fork by the plurality of pins; and
a third process in which the transfer mechanism is retracted from the buffer chamber in a state in which the second substrate is lifted by the plurality of pins,
wherein, in the first process, if a placement position of the second substrate on the lower fork is misaligned, the transfer mechanism is moved to a position where there is no misalignment with respect to the first substrate mounted on the mounting part, and then the first substrate is lifted by the upper fork, and
in the second process, the transfer mechanism is moved according to the positional misalignment in a state in which the first substrate is lifted by the upper fork to correct the position of the second substrate with respect to the plurality of pins, and then the plurality of pins is raised.

2. (canceled)

3. The substrate transfer method of claim 1, wherein, in the first process, the transfer mechanism is moved to a position where there is no positional misalignment with respect to the first substrate mounted on the mounting part and then the first substrate is lifted by the upper fork if the placement position of the second substrate on the lower fork is misaligned by more than an allowable value, and the transfer mechanism is moved to a position where there is no positional misalignment of the second substrate on the lower fork with respect to the plurality of pins and then the first substrate is lifted by the upper fork if the positional misalignment of the second substrate on the lower fork is less than the allowable value, and
in the second process, if the placement position of the second substrate on the lower fork is misaligned by more than the allowable value, the transfer mechanism is moved according to the positional misalignment in a state in which the first substrate is lifted by the upper fork to correct the position of the second substrate with respect to the plurality of pins, and then the plurality of pins is raised, and if the positional misalignment of the second substrate on the lower fork is less than the allowable value, the plurality of pins is raised without changing the position of the lower fork in a state in which the first substrate is lifted by the upper fork.

4. The substrate transfer method of claim 3, wherein, in the second process, if the placement position of the second substrate on the lower fork is misaligned by more than the allowable value, the transfer mechanism is moved by an amount of the positional misalignment to correct the position of the second substrate with respect to the plurality of pins.

5. The substrate transfer method of claim 1, wherein, in the first process, if the placement position of the second substrate on the lower fork is misaligned, the transfer mechanism is moved according to the positional misalignment to correct the position of the second substrate with respect to the plurality of pins, and then the first substrate mounted on the mounting part is lifted by the upper fork.

6. The substrate transfer method of claim 5, wherein, in the first process, if the placement position of the second substrate on the lower fork is misaligned by more than an allowable value, the transfer mechanism is moved to a position where the positional misalignment of the second substrate with respect to the plurality of pins is less than the allowable value, and then the first substrate mounted on the mounting part is lifted by the upper fork.

7. A substrate transfer method of a transfer device having a transfer chamber provided with a transfer mechanism having an upper fork and a lower fork, on an upper side and a lower side, capable of supporting a substrate, and a buffer chamber connected to the transfer chamber, the buffer chamber provided with a mounting part capable of mounting a substrate by contacting a portion of the substrate, and provided with a plurality of pins capable of supporting the substrate by being raised and lowered and provided below the mounting part, the substrate transfer method comprising:
causing the transfer mechanism having a first substrate supported by the upper fork to enter the buffer chamber in which a second substrate is supported by the plurality of pins, and lowering the plurality of pins to place the second substrate on the lower fork;
mounting the first substrate supported by the upper fork on the mounting part in a state in which the second substrate is mounted on the lower fork; and
retracting the transfer mechanism from the buffer chamber in a state in which the second substrate is mounted on the lower fork.

8. The substrate transfer method of claim 7, wherein the first substrate is a substrate which is not subjected to predetermined processing, and the second substrate is a substrate on which the predetermined processing has been performed.

9. A substrate transfer device comprising:
a transfer chamber provided with a transfer mechanism having an upper fork and a lower fork, on an upper side and a lower side, capable of supporting a substrate;
a buffer chamber connected to the transfer chamber, the buffer chamber provided with a mounting part capable of mounting a substrate by contacting a portion of the substrate, and provided with a plurality of pins capable of supporting the substrate by being raised and lowered and provided below the mounting part; and
a controller for executing control of causing the transfer mechanism having a second substrate supported by the lower fork to enter the buffer chamber in which a first substrate is mounted on the mounting part, lifting the first substrate mounted on the mounting part by the upper fork, raising the plurality of pins in a state in which the first substrate is lifted by the upper fork to lift the second substrate supported by the lower fork using the plurality of pins, and retracting the transfer mechanism from the buffer chamber in a state in which the second substrate is lifted by the plurality of pins.

10. A substrate transfer device comprising:
a transfer chamber provided with a transfer mechanism having an upper fork and a lower fork, on an upper side and a lower side, capable of supporting a substrate;
a buffer chamber connected to the transfer chamber, the buffer chamber provided with a mounting part capable of mounting a substrate by contacting a portion of the substrate, and provided with a plurality of pins capable of supporting the substrate by being raised and lowered and provided below the mounting part; and
a controller for executing control of causing the transfer mechanism having a first substrate supported by the upper fork to enter the buffer chamber in which a second substrate is supported by the plurality of pins, lowering the plurality of pins to place the second substrate on the lower fork, mounting the first substrate supported by the upper fork on the mounting part in a state in which the second substrate is mounted on the lower fork, and retracting the transfer mechanism from the buffer chamber in a state in which the second substrate is mounted on the lower fork.
